(19) United States
(12) Patent Application Publication
(10) Pub. No.: US 2026/0304665 A1
(43) Pub. Date: Oct. 1, 2026

(54) CONVERTER TOWER WITH ELECTROMAGNETIC INTERFERENCE SUPPRESSOR, AND CONVERTER INSTALLATION

(71) Applicant: Siemens Energy Global GmbH & Co. KG, München (DE)

(72) Inventors: Torsten Priebe, Möhrendorf (DE); Christopher Eismann, Eggolsheim (DE); Luigi De Marinis, Nürnberg (DE); Christoph Schlereth, Oberthulba (DE); Christian Schrammel, Burgthann (DE); Günter Seibert, Fürth (DE); Erika Stenglein, Hiltpoltstein (DE); Heiko Rabus, Geyern (DE); Michael Vieth, Nürnberg (DE); Anne-Christine Leicht, Erlangen (DE); Stefan Stingl, Nürnberg (DE)

(21) Appl. No.: 19/632,679

(22) Filed: Mar. 30, 2026

(30) Foreign Application Priority Data
Mar. 28, 2025 (EP) 25166872

(51) Int. Cl. H05K 7/02; H02M 1/44; H02M 7/00; H05K 7/10

(52) U.S. Cl. CPC H05K 7/023; H05K 7/10; H02M 1/44; H02M 7/003

(57) ABSTRACT

A converter tower includes a plurality of converter modules and a plurality of electrical connecting conductors. One such connecting conductor connects every two of the converter modules to one another or connects one of the converter modules to a connection line of the converter tower. In order to suppress emissions effectively in a simple manner, at least one of the electrical connecting conductors is provided with an electromagnetic interference suppressor. A converter installation having a plurality of converter towers is also provided.

### CROSS-REFERENCE TO RELATED APPLICATION

This application claims the priority, under 35 U.S.C. § 119, of German Patent Application EP 25166872.9, filed Mar. 28, 2025; the prior application is herewith incorporated by reference in its entirety.

### FIELD AND BACKGROUND OF THE INVENTION

The invention relates to a converter tower with a plurality of converter modules, in particular connected in series, with a plurality of electrical connecting conductors, one such connecting conductor connecting every two of the converter modules of the converter tower to one another or connecting one of the converter modules to a connection line of the converter tower.

Converter towers can form part of converter installations, which in turn can be used in high-voltage direct current transmission (HVDC). The converter towers are typically disposed in valve halls. The converter towers can be disposed either standing or suspended in the valve hall. In particular, the converters can be inverters. Converter modules are also known as power modules or sub-modules.

Switching in the converter modules can generate undesired high-frequency transient interference currents. The conducted and radiated interference caused by the operation of the HVDC converter is based on physical processes that occur when a converter sub-module is switched. Sharp voltage spikes arise at the connections of a converter sub-module as a result of the switching thereof (applying the DC link voltage from a sub-module capacitor). The rise and fall times occur within a few microseconds, and so those voltage spikes give rise to undesired high-frequency transient interference currents. Wherever high-voltage conductors exit the shielded valve hall, the conducted interference can also spread to the air-insulated switchgear and to the high-voltage lines connected thereto in the exterior portion of the HVDC station. In those regions, the interference signals can also radiate out into the environment and thereby be the source of emitted interference from the HVDC station. As a result of a stochastic frequency distribution of the switching of the converter sub-modules, a wideband electromagnetic interference signal is created which can be considered as continuous.

Limiting of the emitted electromagnetic interference from the HVDC station can be required so that third-party devices and systems in the vicinity of the HVDC station (in the kilometer range) are not prevented from operating correctly. Such devices and systems include radio equipment for example.

In order to prevent, or at least suppress, emitted interference, it is known practice to install interference suppression chokes outside the valve hall on the AC or DC lines.

### SUMMARY OF THE INVENTION

It is accordingly an object of the invention to provide a converter tower with electromagnetic interference suppressor and a converter installation, which overcome the hereinafore-mentioned disadvantages of the heretofore-known devices of this general type and which suppress electromagnetic interference signals emanating from converter installations in a simple and effective manner.

With the foregoing and other objects in view there is provided, in accordance with the invention, a converter tower having a plurality of converter modules, and a plurality of electrical connecting conductors, one such connecting conductor connects every two of the converter modules to one another or connects one of the converter modules to a connection line of the converter tower, and at least one of the electrical connecting conductors is provided with an electromagnetic interference suppressor.

With the objects of the invention in view, there is concomitantly provided a converter installation with a plurality of converter towers according to the invention.

The arrangement of an interference suppressor on a connecting conductor of a converter tower ensures that the interference is suppressed close to its source. This provides for efficient suppression.

Because the voltages inside a converter tower are lower than the voltages on the transmission lines outside the valve hall, the dimensions of the interference suppressors can be smaller. In contrast to interference suppressors outside the converter towers which require large insulated sections due to the high voltages, the insulated sections can be smaller in the converter towers because of the lower voltages. As a result, interference suppression can even be implemented anywhere.

The term “connecting conductor” should be understood to mean the electrical conductors that transfer electrical power between the converter modules. A connecting conductor can be an electrical conductor between two converter modules of the same converter tower. Additionally, a connecting conductor can form a connection between a converter module of a converter tower and a connection line, via which this converter tower is connected to another component of the converter installation, in particular to another converter tower. In both cases, the electrical connecting conductors are located on or in the converter tower. The term should not be understood to mean any potential data or control lines.

The solution according to the invention may be improved further by different embodiments that are each advantageous on their own and may be combined with one another as desired. These embodiments and the advantages associated therewith will be discussed below.

According to a first advantageous embodiment of the converter tower, the converter tower can include a plurality of levels disposed one above another, wherein a subset of the plurality of converter modules is disposed on each level, and wherein each level is provided with at least one electromagnetic interference suppressor. It is known practice to configure converter towers with a plurality of levels. Each level is typically equipped with a plurality of converter modules. The number of interference suppressors can correspond to the number of converter modules on a level. Preferably, the number of electromagnetic interference suppressors per level is smaller than the number of converter modules on the level. Particularly preferably, each level is provided with exactly one electromagnetic interference suppressor.

The converter modules of a converter tower are typically connected to one another in series. In such a case, the converter modules of a level are often connected to one another in series, wherein the first or last converter module in the series of converter modules of one level is electrically connected to the first or last converter module in a series of converter modules of another level by one of the electrical connecting conductors. According to one advantageous embodiment, at least one electromagnetic interference suppressor of a level can be disposed on such an electrical connecting conductor that connects two converter modules of adjacent, in particular stacked, levels to one another.

At least some of the electrical connecting conductors can take the form of busbars.

Preferably, at least one electrical connecting conductor is provided with a round cross section at least in the region in which one of the electromagnetic interference suppressors is disposed. In this region, the electrical connecting conductor can take the form in particular of a round conductor, preferably made of copper or a copper-containing material. Upstream and downstream of the region in which the electromagnetic interference suppressor is disposed, the electrical connecting conductor can take the form of a busbar. Of course, the round conductor is electrically connected to the rest of the electrical connecting conductor which is in the form of a busbar. The round conductor can additionally be mechanically connected to the busbar by suitable fastening measures and held by the busbars. If greater mechanical stability is required, the round conductor can also be connected to the converter tower, in particular to a frame of the converter tower, by insulating fastening measures. This may prevent the busbars from having to bear the weight of the interference suppressor, since they are typically made of a soft material.

In order to obtain interference suppressors that are simultaneously effective, simple in configuration and easy to produce, at least one, preferably all, of the electromagnetic interference suppressors can be made up of a plurality of magnetic toroidal cores, wherein central openings of the toroidal cores are disposed so as to be aligned with one another and form a channel, wherein one of the electrical connecting conductors at least partially extends through the channel. The central openings are preferably circular. As already described hereinabove, the section of the electrical connecting conductor on which the interference suppressor is disposed can be circular in cross section. The electrical connecting conductor and the toroidal cores can thus be shaped complementarily with respect to one another. Preferably, an electrically insulating layer is provided between the connecting conductor and the toroidal cores, for example air or a plastic.

The individual toroidal cores are preferably stacked. Such a stack of toroidal cores is also referred to as a suppression kit. The magnetic toroidal cores can be made from ferrites, preferably from iron powder. The stack of toroidal cores can be enclosed in an electrically insulating casing, wherein the casing includes openings for the routing of the connecting conductor.

Preferably, the at least one electromagnetic interference suppressor is configured to suppress frequencies from 0.009-30 MHz, in particular frequencies from 0.5-30 MHz.

For further explanation of the invention, reference is made, in the following part of the description, to figures from which further advantageous details and possible areas of application of the invention may be gleaned. The figures should be understood to be exemplary and are intended to illustrate the character of the invention, but in no way restrict it or even reproduce it definitively. The same reference signs are always used for elements having the same structure and/or the same function.

Other features which are considered as characteristic for the invention are set forth in the appended claims.

Although the invention is illustrated and described herein as embodied in a converter tower with an electromagnetic interference suppressor and a converter installation, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, perspective view of one exemplary embodiment of a converter tower;

FIG. 2 is a fragmentary, perspective view of the converter tower of FIG. 1;

FIG. 3 is a perspective view of an interference suppressor on a connecting conductor; and

FIG. 4 is a diagram showing a simulation of the emissions from a converter installation with and without electromagnetic interference suppressors.

### DETAILED DESCRIPTION OF THE INVENTION

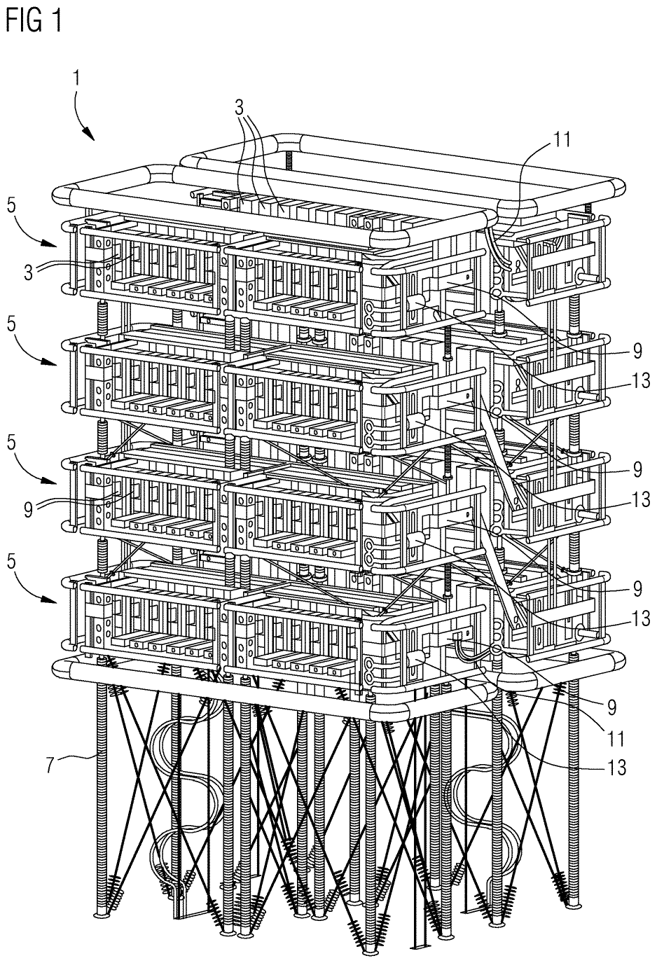

Referring now to the figures of the drawings in detail and first, particularly, to FIG. 1 thereof, there is seen a converter tower 1 which will first be described below.

The converter tower 1 is typically part of a converter installation (not shown), which includes a plurality of converter towers 1.

The converter tower 1 includes a plurality of converter modules 3. Converter modules 3 are also known as power modules or sub-modules. Each of the converter modules 3 can include switching units, which can each be composed of power semiconductor switches and diodes. The switching units of a converter module 3 can be connected to one another in half-bridge or full-bridge configuration, for example. For the sake of clarity, only a small number of converter modules 3 are referenced in FIG. 1.

The converter tower 1 includes a plurality of levels 5 disposed one above another, on which the converter modules 3 are disposed. Each level 5 is equipped with a plurality of converter modules 3. The converter tower 1 shown by way of example includes four levels in total; however, this number is not mandatory.

The converter tower 1 shown in FIG. 1 is provided with supports 7 so that it can be stood in a valve hall. As an alternative to the standing arrangement, the converter tower 1 can also be suspended in the valve hall. The supports 7 can then be omitted.

The converter modules 3 of at least one level 5 of the converter tower 1, preferably all of the converter modules 3 of the converter tower 1, are connected to one another in series. Every two converter modules 3 connected one after the other in series are then connected to one another by a connecting conductor 9. Since the series connection also extends across the levels 5, converter modules 3 of different levels 5 are also connected to one another by connecting conductors 9.

Multiple converter towers 1 can be connected to one another via connection lines 11. A connection line can be connected to the first or last converter module 3 of a converter tower 1 via a connecting conductor 9 on the converter tower 1.

Of the four connecting conductors 9 visible at the front right in FIG. 1, three each connect a converter module 3 of one level 5 to a converter module 3 of another level 5. The fourth connecting conductor 9, which in FIG. 1 is the lowest connecting conductor 9, connects a converter module 3 of the lowest of the levels 5 to a connection line 11.

One of the connecting conductors 9 on each level 5 is provided with an electromagnetic interference suppressor 13, in order to minimize emitted electromagnetic interference. The converter tower 1 thus includes one electromagnetic interference suppressor 13 per level 5. Alternatively, the converter tower 1 can be provided with a different number of electromagnetic interference suppressors 13.

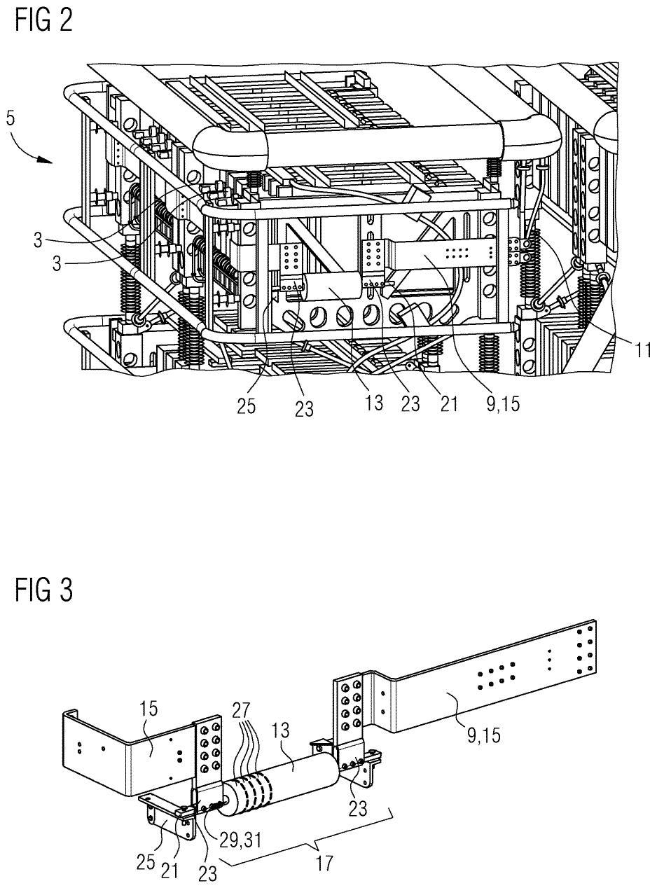

The electromagnetic interference suppressors 13 will now be described with reference to FIGS. 2 and 3.

FIG. 2 shows a detail of a connecting conductor 9 with an electromagnetic interference suppressor 13 and FIG. 3 shows the connecting conductor 9 with the electromagnetic interference suppressor 13 of FIG. 2 without the rest of the converter tower 1.

The electrical connecting conductor 9 is in the form of a busbar 15.

At least in a region 17 in which the electromagnetic interference suppressor 13 is disposed, the electrical connecting conductor 9 has a round cross section. To that end, the electrical connecting conductor 9 takes the form of a round conductor 21 as it passes through the region 17, and is electrically connected to the remaining electrical connecting conductor 9 which is in the form of a busbar 15 by suitable connecting elements 23.

In addition, the round conductor 21 is connected to fastening elements 25 which can be fastened to suitable components of the converter tower 1. This may prevent the busbar 15 from having to bear the weight of the electromagnetic interference suppressor 13. The fastening elements 25 can be made from electrically insulating material.

The previously described type of arrangement of the electromagnetic interference suppressors 13 on the converter tower 1 allows them to be installed anywhere in the converter tower 1. Additionally, such an electromagnetic interference suppressor 13 can easily be retrofitted.

The electromagnetic interference suppressor 13 is a hollow cylinder in overall shape, wherein the round conductor 21 extends through the interior of the hollow cylinder. The electromagnetic interference suppressor 13 is preferably made up of a plurality of magnetic toroidal cores 27. This is indicated in FIG. 3 by a dashed line. Central openings 29 of the toroidal cores 27 are disposed so as to be aligned with one another and form a channel 31 for the round conductor 21, which extends through the channel 31.

The electromagnetic interference suppressor 13 is preferably configured to suppress frequencies from 0.009-30 MHz, in particular from 0.5-30 MHz.

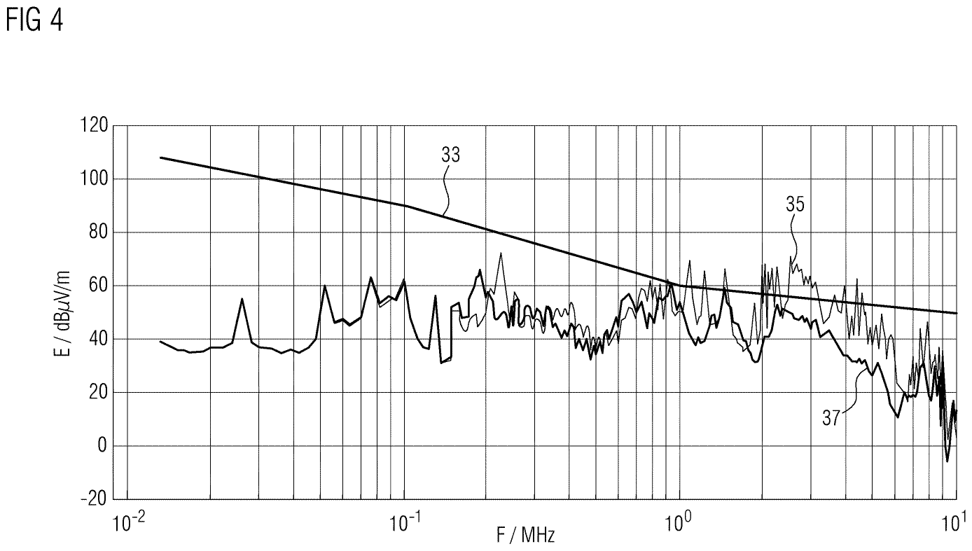

FIG. 4 shows a simulation of the emissions from a converter installation with and without electromagnetic interference suppressors. The X-axis represents the frequency F in MHz and the Y-axis represents the emission E in dBμV/m.

The solid line 33 represents the maximum permissible emission based on recommendations according to CIGRE 391 (CIGRE: Conseil International des Grands Réseaux Électriques). The curve referenced 35 represents a simulation of the emission from a converter installation without electromagnetic interference suppressors. The curve referenced 37 represents the emission from a converter installation of which the converter towers 1 are provided with the electromagnetic interference suppressors 13.

The emission from the installation provided with the electromagnetic interference suppressors 13 remains below the recommendations according to CIGRE 391 throughout the entire frequency range.

The following is a summary list of reference numerals and the corresponding structure used in the above description of the invention:
1 Converter tower
3 Converter module
5 Level
7 Support
9 Connecting conductor
11 Connection line
13 Electromagnetic interference suppressor
15 Busbar
17 Region of the connecting conductor
21 Round conductor
23 Connecting element
25 Fastening element
27 Toroidal core
29 Central opening
31 Channel
33 Permissible emission
35 Emission without interference suppressors
37 Emission with interference suppressors

1. A converter tower, comprising:
a plurality of connection lines;
a plurality of converter modules;
a plurality of electrical connecting conductors;
a respective one of said plurality of electrical connecting conductors connecting every respective two of said plurality of converter modules to one another, or
a respective one of said plurality of electrical connecting conductors connecting a respective one of said plurality of converter modules to a respective one of said plurality of connection lines; and
at least one of said plurality of electrical connecting conductors having an electromagnetic interference suppressor.

2. The converter tower according to claim 1, which further comprises a plurality of levels disposed one above another, said plurality of converter modules including a subset of converter modules disposed on each respective level, and each of said levels including at least one said electromagnetic interference suppressor.

3. The converter tower according to claim 2, wherein each of said levels is provided with exactly one said electromagnetic interference suppressor.

4. The converter tower according to claim 2, wherein said at least one electromagnetic interference suppressor of a level is disposed on an electrical connecting conductor connecting two of said plurality of converter modules of adjacent levels to one another.

5. The converter tower according to claim 1, wherein at least one of said plurality of electrical connecting conductors is a busbar.

6. The converter tower according to claim 1, wherein at least one of said plurality of electrical connecting conductors has a round cross section at least in a region in which one of said plurality of electromagnetic interference suppressors is disposed.

7. The converter tower according to claim 1, wherein:
at least one of said plurality of electromagnetic interference suppressors is made up of a plurality of magnetic toroidal cores;
said toroidal cores have central openings formed therein and disposed so as to be aligned with one another and form a channel; and
one of said plurality of electrical connecting conductors at least partially extends through said channel.

8. The converter tower according to claim 1, wherein said electromagnetic interference suppressor is configured to suppress frequencies of from 0.009-30 MHz.

9. The converter tower according to claim 1, wherein said electromagnetic interference suppressor is configured to suppress frequencies of from 0.5-30 MHz.

10. A converter installation, comprising a plurality of converter towers according to claim 1.
